(19) United States
(12) Patent Application Publication
(10) Pub. No.: US 2025/0234762 A1
(43) Pub. Date: Jul. 17, 2025

(54) DISPLAY PANEL AND MANUFACTURE METHOD THEREOF, DISPLAY DEVICE

(71) Applicants: Chengdu BOE Optoelectronics Technology Co., Ltd., Chengdu (Sichuan) (CN); BOE TECHNOLOGY GROUP CO., LTD., Beijing (CN)

(72) Inventors: Cheng LIU, Beijing (CN); Jiandong BAO, Beijing (CN); Puyu QI, Beijing (CN); Xueguang HAO, Beijing (CN); Jianbo XIAN, Beijing (CN)

(73) Assignees: Chengdu BOE Optoelectronics Technology Co., Ltd., Chengdu (Sichuan) (CN); BOE TECHNOLOGY GROUP CO., LTD., Beijing (CN)

(21) Appl. No.: 18/691,539

(22) PCT Filed: Jul. 25, 2023
(86) PCT No.: PCT/CN2023/109065

§ 371 Date: Mar. 13, 2024

(51) Int. Cl. H10K 59/80; G06F 3/041; H10K 59/12; H10K 59/122; H10K 59/40

(52) U.S. Cl. CPC H10K 59/8792; G06F 3/0412; H10K 59/1201; H10K 59/122; H10K 59/40; H10K 59/873; G06F 2203/04103

(57) ABSTRACT

A display panel, a manufacture method thereof, and a display device are provided, the display panel includes a base substrate, a driving circuit layer, a light-emitting device layer, an encapsulation layer, and a gray planarization layer; the display panel is provided with a main display region (AA), a sensor region (SS) and a light-transmitting display region (FDC), the main display region (AA) at least partially surrounds the sensor region (SS) and the light-transmitting display region (FDC), and the gray planarization layer (GO) is in the main display region (AA), the sensor region (SS) and the light-transmitting display region (FDC).

### TECHNICAL FIELD

Embodiments of the present disclosure relate to a display panel and a manufacture method thereof, and a display device.

### BACKGROUND

Organic light emitting diode (OLED) display devices have a series of advantages such as self-illumination, high contrast, high definition, wide viewing angle, low power consumption, fast response speed, and low manufacturing cost, have become one of the key development directions of the new generation of display devices, and therefore have received more and more attention. At present, how to optimize the structure of the display device is a subject of constant research for those skilled in the art.

### SUMMARY

At least one embodiment of the present disclosure provides a display panel, the display panel comprises a base substrate, a driving circuit layer, a light-emitting device layer, an encapsulation layer, and a gray planarization layer, the driving circuit layer is on the base substrate, the light-emitting device layer is on a side of the driving circuit layer away from the base substrate, the encapsulation layer is on a side of the light-emitting device layer away from the base substrate, and the gray planarization layer is on a side of the encapsulation layer away from the base substrate; the display panel is provided with a main display region, a sensor region and a light-transmitting display region, the main display region at least partially surrounds the sensor region and the light-transmitting display region, and the gray planarization layer is in the main display region, the sensor region and the light-transmitting display region.

For example, the display panel provided by at least one embodiment of the present disclosure further comprises a black matrix layer on a side of the encapsulation layer away from the base substrate, the gray planarization layer is on a side of the black matrix layer away from the base substrate.

For example, in the display panel provided by at least one embodiment of the present disclosure, the main display region comprises a plurality of first sub-pixels, each of the plurality of first sub-pixels comprises a first light-emitting device in the light-emitting device layer, the sensor region comprises a plurality of second sub-pixels, each of the plurality of second sub-pixels comprises a second light-emitting device in the light-emitting device layer, the black matrix layer comprises a plurality of first light exit openings exposing first light-emitting devices in the main display region, a plurality of second light exit openings exposing second light-emitting devices in the sensor region, and a first sensor opening between the plurality of second light exit openings.

For example, in the display panel provided by at least one embodiment of the present disclosure, a material of the gray planarization layer is filled in the plurality of first light exit openings, the plurality of second light exit openings and the first sensor opening, an area of the material of the gray planarization layer filled in the plurality of first light exit openings is greater than an area of the material of the gray planarization layer filled in the first sensor opening, and an area of the material of the gray planarization layer filled in the plurality of second light exit openings is larger than the area of the material of the gray planarization layer filled in the first sensor opening.

For example, in the display panel provided by at least one embodiment of the present disclosure, the light-transmitting display region comprises a plurality of third sub-pixels, each of the plurality of third sub-pixels comprises a third light-emitting device in the light-emitting device layer, an arrangement density of first light-emitting devices in the main display region is equal to an arrangement density of third light-emitting devices in the light-transmitting display region, a ratio of a light-emitting area of the third light-emitting device to a light-emitting area of the first light-emitting device ranges from 1:4 to 1:2, in the light-transmitting display region, the black matrix layer comprises a plurality of annular light-shielding portions respectively exposing the third light-emitting devices of the plurality of third sub-pixels, and the plurality of the annular light-shielding portions are arranged at intervals.

For example, in the display panel provided by at least one embodiment of the present disclosure, an area of a material of the gray planarization layer filled in the plurality of the annular light-shielding portions is larger than an area of a material of the gray planarization layer filled in the first sensor opening.

For example, in the display panel provided by at least one embodiment of the present disclosure, the first light-emitting device comprises a first anode pattern, a first light-emitting pattern and a first cathode layer that are arranged in a stack, first cathode layers of first light-emitting devices of the plurality of first sub-pixels are continuously arranged in the main display region, the third light-emitting device of each of the plurality of third sub-pixels comprises a third anode pattern, a third light-emitting pattern and a third cathode pattern that are arranged in a stack, and third cathode patterns of third light-emitting devices of the plurality of third sub-pixels are arranged at intervals in the light-transmitting display region.

For example, in the display panel provided by at least one embodiment of the present disclosure, the light-emitting device layer further comprises a pixel definition layer for defining sub-pixels, the pixel definition layer comprises a plurality of sub-pixel openings in the main display region, the sensor region and the light-transmitting display region; in the sensor region, the pixel definition layer comprises a second sensor opening at least partially overlapping with the first sensor opening in a direction perpendicular to the base substrate, and in the light-transmitting display region, the pixel definition layer comprises a plurality of sub-pixel walls for defining the plurality of third sub-pixel openings, and the plurality of sub-pixel walls are arranged at intervals.

For example, in the display panel provided by at least one embodiment of the present disclosure, the light-transmitting display region comprises a sub-pixel setting region and a sub-pixel removal region, the sub-pixel setting region comprises a plurality of third sub-pixels, the sub-pixel removal region does not comprise a sub-pixel, a ratio of an area of the sub-pixel setting region to an area of the sub-pixel removal region ranges from 1:3 to 1:1, each of the plurality of third sub-pixels comprises a third light-emitting device in the light-emitting device layer, an arrangement density of first light-emitting devices in the main display region is equal to an arrangement density of third light-emitting devices in the sub-pixel setting region, a light-emitting area of the third light-emitting device is equal to a light-emitting area of the first light-emitting device, the sub-pixel setting region further comprises a plurality of first wiring lines at edges of the plurality of third sub-pixels, in the sub-pixel setting region, the black matrix layer comprises a plurality of first shielding lines at least partially overlapping with the plurality of first wiring lines in a direction perpendicular to the base substrate, and the black matrix layer is hollowed out in the sub-pixel removal region.

For example, in the display panel provided by at least one embodiment of the present disclosure, the light-emitting device layer further comprises a pixel definition layer for defining sub-pixels, and the pixel definition layer is hollowed out in the sub-pixel removal region.

For example, in the display panel provided by at least one embodiment of the present disclosure, in a direction perpendicular to the base substrate, a first thickness of the gray planarization layer in the main display region ranges from 2 μm to 3 μm, a second thickness of the gray planarization layer in the sensor region is higher than the first thickness by 0.2 μm to 0.5 μm, a third thickness of the gray planarization layer in the light-transmitting display region is lower than the first thickness by 0.4 μm to 0.6 μm.

For example, the display panel provided by at least one embodiment of the present disclosure further comprises an anti-reflection layer, in the sensor region and the light-transmitting display region, and on a side of the second light-emitting device or the third light-emitting device away from the base substrate, the encapsulation layer is on a side of the anti-reflection layer away from the base substrate.

For example, in the display panel provided by at least one embodiment of the present disclosure, a material of the anti-reflection layer comprises at least one of ytterbium, bismuth, calcium fluoride and magnesium fluoride, in a direction perpendicular to the base substrate, a thickness of the anti-reflection layer ranges from 8 nm to 10 nm.

For example, in the display panel provided by at least one embodiment of the present disclosure, the light-emitting device layer further comprises a pixel definition layer for defining sub-pixels, the pixel definition layer comprises a plurality of sub-pixel openings in the main display region, the sensor region and the light-transmitting display region; in the main display region, a first orthographic projection of the sub-pixel opening on the base substrate is within a second orthographic projection of the first light exit opening on the base substrate, and in the sensor region, a third orthographic projection of the second light exit opening on the base substrate is within a fourth orthographic projection of the sub-pixel opening on the base substrate.

For example, in the display panel provided by at least one embodiment of the present disclosure, the third orthographic projection is contracted inwardly by 1 μm to 4 μm relative to the fourth orthographic projection.

For example, in the display panel provided by at least one embodiment of the present disclosure, the light-emitting device layer further comprises a pixel definition layer for defining sub-pixels, the pixel definition layer comprises a plurality of sub-pixel openings in the main display region, the sensor region and the light-transmitting display region; in the sensor region, the pixel definition layer comprises a second sensor opening overlapping with the first sensor opening in a direction perpendicular to the base substrate, the second light-emitting device of each of the plurality of second sub-pixels comprises a second anode pattern, a second light-emitting pattern and a second cathode layer that are arranged in a stack, the second cathode layer is continuously arranged in the sensor region, and comprises a third sensor opening overlapping with the first sensor opening in a direction perpendicular to the base substrate.

For example, in the display panel provided by at least one embodiment of the present disclosure, a fifth orthographic projection of the second sensor opening on the base substrate is within a sixth orthographic projection of the third sensor opening on the base substrate.

For example, in the display panel provided by at least one embodiment of the present disclosure, the fifth orthographic projection is contracted inwardly by 1 μm to 2 μm relative to the sixth orthographic projection.

For example, the display panel provided by at least one embodiment of the present disclosure further comprises a touch layer and a black matrix layer, the touch layer on a side of the encapsulation layer away from the base substrate, and comprises a touch wiring layer and a touch insulation layer on a side of the touch wiring layer away from the base substrate, the gray planarization layer is on a side of the touch insulation layer away from the base substrate, and the black matrix layer is on a side of the gray planarization layer away from the base substrate.

For example, the display panel provided by at least one embodiment of the present disclosure further comprises a touch layer and a black matrix layer, the touch layer is on a side of the encapsulation layer away from the base substrate, and comprises a touch wiring layer, the touch wiring layer comprises a plurality of touch wiring lines, the gray planarization layer is on a side of the touch wiring layer away from the base substrate, and is in contact with the plurality of touch wiring lines, and the black matrix layer is on a side of the gray planarization layer away from the base substrate.

For example, the display panel provided by at least one embodiment of the present disclosure further comprises a touch layer and a black matrix layer, the touch layer is on a side of the encapsulation layer away from the base substrate, and comprises a touch wiring layer, the touch wiring layer comprises a plurality of touch wiring lines, and the black matrix layer is on a side of the touch wiring layer away from the base substrate, and comprises a plurality of second shielding lines that contact and cover the plurality of touch wiring lines, the gray planarization layer is on a side of the black matrix layer away from the base substrate.

For example, the display panel provided by at least one embodiment of the present disclosure further comprises a touch layer and a black matrix layer, the black matrix layer is on a side of the encapsulation layer away from the base substrate, the touch layer is on a side of the black matrix layer away from the base substrate, and comprises a touch wiring layer, the touch wiring layer comprises a plurality of touch wiring lines, the gray planarization layer is on a side of the touch wiring layer away from the base substrate.

For example, the display panel provided by at least one embodiment of the present disclosure further comprises a molybdenum oxide layer, on a side of the plurality of touch wiring lines away from the base substrate, and comprising a plurality of covering lines to cover the plurality of touch wiring lines.

For example, the display panel provided by at least one embodiment of the present disclosure further comprises a black matrix layer and a transparent insulating layer, the black matrix layer is on a side of the encapsulation layer away from the base substrate, and comprises a plurality of light-shielding patterns, the transparent insulating layer is on a side of the black matrix layer away from the base substrate, and comprises a plurality of covering patterns, the plurality of covering patterns respectively cover the plurality of light-shielding patterns, the gray planarization layer is on a side of the transparent insulating layer away from the base substrate.

For example, in the display panel provided by at least one embodiment of the present disclosure, a refractive index of the transparent insulating layer is n1, a refractive index of the gray planarization layer is n2, and n1<n2.

For example, in the display panel provided by at least one embodiment of the present disclosure, n2−n1≥0.05.

For example, in the display panel provided by at least one embodiment of the present disclosure, a light transmittance of the gray planarization layer ranges from 40% to 60%.

For example, in the display panel provided by at least one embodiment of the present disclosure, the gray planarization layer comprises a transparent matrix and a light-absorbing material dispersed in the transparent matrix.

For example, in the display panel provided by at least one embodiment of the present disclosure, the light-absorbing material comprises at least one of an oxazine compound, an anthocyanin compound, a tetraazaporphyrin compound and a squaraine compound.

At least one embodiment of the present disclosure further provides a display device, the display device comprises the display panel provided by the embodiments of the present disclosure.

At least one embodiment of the present disclosure further provides a manufacture method of a display panel, which comprises: providing a base substrate, forming a driving circuit layer on the base substrate, forming a light-emitting device layer on a side of the driving circuit layer away from the base substrate, forming an encapsulation layer on a side of the light-emitting device layer away from the base substrate, and forming a gray planarization layer on a side of the encapsulation layer away from the base substrate; in which the display panel is provided with a main display region, a sensor region and a light-transmitting display region, the main display region at least partially surrounds the sensor region and the light-transmitting display region, and the gray planarization layer is formed in the main display region, the sensor region and the light-transmitting display region.

### BRIEF DESCRIPTION OF DRAWINGS

In order to clearly illustrate technical solutions of the embodiments of the present disclosure, the drawings of the embodiments will be briefly described. It is obvious that the described drawings in the following are only related to some embodiments of the present disclosure and thus are not construed as any limitation to the present disclosure.

FIG. 1 is a planar schematic diagram of a display panel provided by at least one embodiment of the present disclosure;

FIG. 2 is a partial cross-sectional schematic diagram of a display panel provided by at least one embodiment of the present disclosure;

FIG. 3 is a partial planar schematic diagram of a main display region, a sensor region and a light-transmitting display region in a display panel provided by at least one embodiment of the present disclosure;

FIG. 4 is a partial cross-sectional schematic diagram of another display panel provided by at least one embodiment of the present disclosure;

FIG. 5A is a partial planar schematic diagram of a main display region, a sensor region and a light-transmitting display region in a display panel provided by at least one embodiment of the present disclosure;

FIG. 5B is a partial planar schematic diagram of a black matrix in a main display region, a sensor region and a light-transmitting display region of a display panel provided by at least one embodiment of the present disclosure;

FIG. 6 is a partial cross-sectional schematic diagram of further another display panel provided by at least one embodiment of the present disclosure;

FIG. 7 is a partial cross-sectional schematic diagram of yet another display panel provided by at least one embodiment of the present disclosure;

FIG. 8 is a schematic diagram of reduction principle of an anti-reflection layer in a display panel provided by at least one embodiment of the present disclosure;

FIG. 9 is a partial cross-sectional schematic diagram of yet another display panel provided by at least one embodiment of the present disclosure;

FIG. 10 is a partial planar schematic diagram of a main display region, a sensor region and a light-transmitting display region in further another display panel provided by at least one embodiment of the present disclosure;

FIG. 11 is a partial cross-sectional schematic diagram of yet another display panel provided by at least one embodiment of the present disclosure;

FIG. 12 is a partial planar schematic diagram of a main display region, a sensor region and a light-transmitting display region in yet another display panel provided by at least one embodiment of the present disclosure;

FIG. 13 is a partial cross-sectional schematic diagram of yet another display panel provided by at least one embodiment of the present disclosure;

FIG. 14 is a partial cross-sectional schematic diagram of yet another display panel provided by at least one embodiment of the present disclosure;

FIG. 15 is a partial cross-sectional schematic diagram of yet another display panel provided by at least one embodiment of the present disclosure;

FIG. 16 is a partial cross-sectional schematic diagram of yet another display panel provided by at least one embodiment of the present disclosure;

FIG. 17 is a partial cross-sectional schematic diagram of yet another display panel provided by at least one embodiment of the present disclosure;

FIG. 18 is a partial cross-sectional schematic diagram of yet another display panel provided by at least one embodiment of the present disclosure;

FIG. 19 is a planar schematic diagram of a main display region of a display panel provided by at least one embodiment of the present disclosure; and

FIG. 20 is a planar schematic diagram of a sensor region in a display panel provided by at least one embodiment of the present disclosure.

### DETAILED DESCRIPTION

In order to make objectives, technical details, and advantages of the embodiments of the present disclosure clearer, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components Also, the terms “comprise,” “comprising.” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “left,” “right” and the like are only used to indicate relative position relationship, and when the position of the object which is described is changed, the relative position relationship may be changed accordingly.

As users have higher and higher demands for display devices such as mobile phones and tablet computers and as display technology continues to develop, users have increasingly strong requirements for low-thickness display devices. Color filter on encapsulation (COE) technology reduces the reflectivity by forming a black matrix (BM) and a color filter (CF) above an encapsulation layer, thereby replacing a circular polarizer.

In COE technology, color filters of different colors are respectively placed above the light-emitting layers of the light-emitting devices of the sub-pixels of corresponding colors, the color filters of different colors have high light transmittance, allowing the light emitted by the light-emitting device to pass through, an interval region between the light-emitting devices is blocked by the black matrix, and the black matrix can absorb most of the external light to achieve the effect of reducing reflection and increasing transparency.

At present, a thickness of the circular polarizer used for the flexible OLED displays is about 50 μm, and COE technology can control the thickness below 5 μm, which can greatly reduce the thickness of the display device. However, users are still pursuing thinner display device, and manufacturers are still pursuing simpler manufacture processes.

At least one embodiment of the present disclosure provides a display panel, a manufacture method thereof, and a display device, the display panel includes a base substrate, a driving circuit layer, a light-emitting device layer, an encapsulation layer and a gray planarization layer; the driving circuit layer is arranged on the base substrate, and the light-emitting device layer is arranged on a side of the driving circuit layer away from the base substrate, the encapsulation layer is arranged on a side of the light-emitting device layer away from the base substrate, and the gray planarization layer is arranged on a side of the encapsulation layer away from the base substrate; in which the display panel is provided with a main display region, a sensor region and a light-transmitting display region, the main display region at least partially surrounds the sensor region and the light-transmitting display region, and the gray planarization layer is arranged in the main display region, the sensor region and the light-transmitting display region.

The above display panel provided by the embodiments of the present disclosure uses the gray planarization layer to replace the color filters in COE technology, thereby reducing the manufacturing difficulty of the display panel, for example, reducing the number of masks required for forming the color filters, reducing consumption of color filter materials, and at the same time, achieving reduction in reflection and increasing in transmission and the thinning of the display panel.

The display panel, the manufacture method thereof, and the display device provided by the embodiments of the present disclosure will be described in detail below through several specific embodiments.

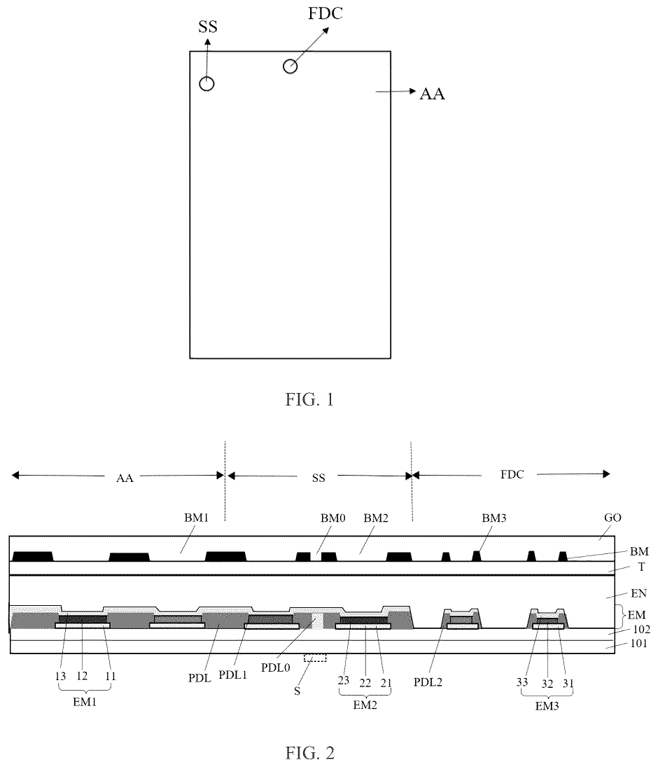

At least one embodiment of the present disclosure provides a display panel. FIG. 1 shows a planar schematic diagram of the display panel, and FIG. 2 shows a partial cross-sectional schematic diagram of the display panel. As shown in FIG. 1 and FIG. 2, the display panel includes a base substrate 101, a driving circuit layer 102, a light-emitting device layer EM, an encapsulation layer EN, a gray planarization layer GO and other structures.

As shown in FIG. 1 and FIG. 2, the driving circuit layer 102 is arranged on the base substrate 101, and includes a plurality of pixel driving circuits. For example, each of the plurality of pixel driving circuits includes a plurality of thin film transistors and a plurality of storage capacitors, for example, may be formed into 3T1C (that is, including three thin film transistors and one storage capacitor), 7T1C (that is, including seven thin film transistors and one storage capacitor), 8T1C (that is, including eight thin film transistors and one storage capacitor), 8T2C (that is, including eight thin film transistors and two storage capacitors), or other forms, and the embodiments of the present disclosure do not limit the forms of the plurality of pixel driving circuits in the driving circuit layer 102.

The light-emitting device layer EM is arranged on a side of the driving circuit layer 102 away from the base substrate 101, and includes a plurality of light-emitting devices. The plurality of pixel driving circuits in the driving circuit layer 102 are configured to drive the plurality of light-emitting devices in the light-emitting device layer EM to emit light, thereby realizing display. The plurality of light-emitting devices may be, for example, OLED display devices or QLED display devices.

The encapsulation layer EN is arranged on a side of the light-emitting device layer EM away from the base substrate 101 to encapsulate the plurality of light-emitting devices in the light-emitting device layer EM. The encapsulation layer EN may be, for example, a composite encapsulation layer, including a plurality of sub-encapsulation layers, such as a stack of a plurality of inorganic encapsulation sub-layers and at least one organic encapsulation sub-layer, for example, the inorganic encapsulation sub-layer may adopt an inorganic insulating material such as silicon oxide, silicon nitride and silicon oxynitride, the organic encapsulation sub-layer may adopt an organic insulating material such as polyimide and resin. The embodiments of the present disclosure do not limit the specific form of the encapsulation layer EN.

The gray planarization layer GO is arranged on a side of the encapsulation layer EN away from the base substrate 101.

In the embodiments of the present disclosure, the gray planarization layer GO has a certain grayscale, the light transmittance of the gray planarization layer GO is lower than the light transmittance of the conventional transparent planarization layer. For example, the light transmittance of the gray planarization layer GO may range from 40% to 60%, such as 50% to 60%, such as 55%, while the light transmittance of the conventional transparent planarization layer is usually above 95%.

For example, in some embodiments, the gray planarization layer GO includes a transparent matrix and a light-absorbing material dispersed in the transparent matrix. For example, the transparent matrix may include an organic insulating material such as polyimide and resin; the light-absorbing material may include at least one of dyes or pigments such as an oxazine compound, an anthocyanin compound, a tetraazaporphyrin compound, and a squaraine compound.

For example, in some embodiments, a thickness (that is, the size in the direction perpendicular to the base substrate 101, that is, the size in the vertical direction in FIG. 2) of the gray planarization layer GO may range from 1 μm to 10 μm, such as 2 μm to 8 μm, such as 2 μm to 5 μm, such as 2 μm to 3 μm, such as 2.2 μm, 2.5 μm or 2.7 μm.

For example, in other embodiments, the gray planarization layer GO may also have selective light transmittance, such as selectively absorbing light in the wavelength range of 480 nm-510 nm and 560 nm-590 nm, in this case, a peak transmittance of the gray planarization layer GO ranges from 50% to 60%.

In embodiments of the present disclosure, the gray planarization layer GO can replace the color filters in the traditional COE technology, thereby reducing the manufacturing difficulty of the display panel, for example, reducing the number of masks required for forming the color filters, reducing consumption of color filter materials, and at the same time, achieving reduction in reflection and increasing in transmission and the thinning of the display panel

For example, as shown in FIG. 1, the display panel has a main display region AA, a sensor region SS and a light-transmitting display region FDC. The main display region AA is the most important display region of the display panel. The sensor region SS can also perform display, and sensors, such as an ambient light sensor, can also be set in the sensor region SS, to achieve other functions besides display. The light-transmitting display region FDC is at least partially light-transmitting and can be used to be combined with a camera and other devices to realize functions such as taking photos and videos while displaying.

As shown in FIG. 1, the main display region AA at least partially surrounds the sensor region SS and the light-transmitting display region FDC, that is, the sensor region SS and the light-transmitting display region FDC may be at least partially arranged in the main display region AA, so that the entire of the main display region AA can display.

For example, the gray planarization layer GO is arranged in the main display region AA, the sensor region SS and the light-transmitting display region FDC. In this way, the main display region AA, the sensor region SS and the light-transmitting display region FDC can all use the gray planarization layer GO to replace the color filters in traditional technology, thereby simplifying the manufacture method of the display panel and achieving the purpose of thinning.

For example, in some embodiments, as shown in FIG. 2, the display panel may further include a black matrix layer BM, the black matrix layer BM is arranged on a side of the encapsulation layer EN away from the base substrate 101, and the gray planarization layer GO is arranged on a side of the black matrix layer away from the base substrate 101.

For example, in some embodiments, as shown in FIG. 2, the display panel may further include a touch layer T, the touch layer T is arranged on a side of the encapsulation layer EN away from the base substrate 101, in this case, the black matrix layer BM is arranged on a side of the touch layer T away from the base substrate 101. For example, the touch layer T may include a plurality of touch wiring lines for implementing the touch function.

For example, as shown in FIG. 2, the main display region AA includes a plurality of first sub-pixels, each of the plurality of first sub-pixels includes a first light-emitting device EM1 located in the light-emitting device layer EM, the sensor region SS includes a plurality of second sub-pixels, each of the plurality of second sub-pixels includes a second light-emitting device EM2 located in the light-emitting device layer EM, the black matrix layer BM includes a plurality of first light exit openings BM1 exposing the first light-emitting devices EM1 in the main display region AA, the black matrix layer BM includes a plurality of second light exit openings BM2 exposing the second light-emitting devices EM2 in the sensor region SS and a first sensor opening BM0 located between the plurality of second light exit openings BM2 in the sensor region SS. The plurality of first light exit openings BM1 are used to transmit light emitted by the plurality of first light-emitting devices EM1, the plurality of second light exit openings BM2 are used to transmit the light emitted by the plurality of second light-emitting devices EM2, and the first sensor opening BM0 is used to transmit light for sensor operation.

For example, the sensor region SS is provided with a sensor S, the sensor S may be connected to a side of the base substrate 101 away from the driving circuit layer 102. For example, the sensor S may be an ambient light sensor, and ambient light can be sensed through the first sensor opening BM0.

For example, as shown in FIG. 2, the light-transmitting display region FDC includes a plurality of third sub-pixels, each of the plurality of third sub-pixels includes a third light-emitting device EM3 located in the light-emitting device layer EM. For example, an arrangement density of the first light-emitting devices EM1 in the main display region AA is greater than or equal to an arrangement density of the third light-emitting devices EM3 in the light-transmitting display region FDC, however, a light-emitting area of the third light-emitting device EM3 is smaller than a light-emitting area of the first light-emitting device EM1. For example, a ratio of the light-emitting area of the third light-emitting device EM3 to the light-emitting area of the first light-emitting device EM1 ranges from 1:4 to 1:2, such as 1:2, 1:3 or 1:4, the black matrix layer BM, in the light display region FDC, includes a plurality of annular light-shielding portions BM3 that respectively expose the third light-emitting devices EM3 of the plurality of third sub-pixels, and the plurality of annular light-shielding portions BM3 are arranged at intervals.

In this way, the region in the light-transmitting display region FDC, except the region where the third light-emitting devices EM3 and the plurality of annular light-shielding portions BM3 are arranged, can transmit light. The light-emitting area of the third light-emitting device EM3 being smaller than the light-emitting area of the first light-emitting device EM1 can improve the light transmittance of the light-transmitting display region FDC.

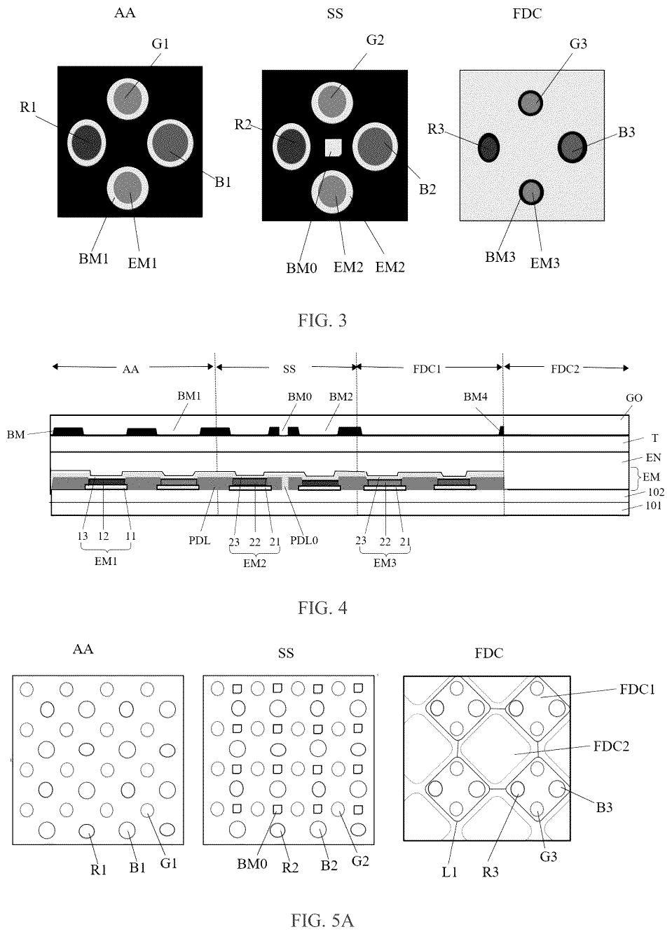

For example, FIG. 3 shows a planar schematic diagram of the black matrix layer BM in the main display region AA, the sensor region SS and the light-transmitting display region FDC, as shown in FIG. 2 and FIG. 3, the material of the gray planarization layer GO is filled in the plurality of first light exit openings BM1, the plurality of second light exit openings BM2 and the first sensor opening BM0. As shown in FIG. 3, an area of the material of the gray planarization layer GO filled in the plurality of first light exit openings BM1 is larger than an area of the material of the gray planarization layer GO filled in the first sensor opening BM0, and an area of the material of the gray planarization layer GO filled in the plurality of second light exit openings BM2 is larger than the area of the material of the gray planarization layer GO filled in the first sensor opening BM0.

For example, as shown in FIG. 3, an area of the material of the gray planarization layer GO filled in the plurality of the annular light-shielding portions BM3 is larger than the area of the material of the gray planarization layer GO filled in the first sensor opening BM0.

For example, in some embodiments, as shown in FIG. 3, in the main display region AA, the plurality of first sub-pixels include a first red sub-pixel R1, a first green sub-pixel G1 and a first blue sub-pixel B1, one first red sub-pixel R1, two first green sub-pixels G1 and one first blue sub-pixel B1 constitute a first repeating unit in the main display region AA, a plurality of first repeating units are arranged in an array in the main display region AA. Similarly, in the sensor region SS, the plurality of second sub-pixels include a second red sub-pixel R2, a second green sub-pixel G2, and a second blue sub-pixel B2, one second red sub-pixel R2, two second green sub-pixels G2 and one second blue sub-pixel B2 constitute a second repeating unit in the sensor region SS, and a plurality of second repeating units are arranged in an array in the sensor region SS. In the light-transmitting display region FDC, the plurality of third sub-pixels include a third red sub-pixel R3, a third green sub-pixel G3 and a third blue sub-pixel B3, one third red sub-pixel R3, two third green sub-pixels G3 and one third blue sub-pixel B3 constitute a third repeating unit in the light-transmitting display region FDC, and a plurality of third repeating units are arranged in an array in the light-transmitting display region FDC.

In this case, the ratio of the light-emitting area of the third light-emitting device EM3 to the light-emitting area of the first light-emitting device EM1, mentioned in the embodiments of the present disclosure, ranges from 1:4 to 1:2, which refers to a comparison of the light-emitting areas of the sub-pixels of the same color, for example, a ratio of the light-emitting area of the third light-emitting device EM3 of the third red sub-pixel R3 to the light-emitting area of the first light-emitting device EM1 of the first red sub-pixel R1 ranges from 1:4 to 1:2, a ratio of the light-emitting area of the third light-emitting device EM3 of the third green sub-pixel G3 to the light-emitting area of the first light-emitting device EM1 of the first green sub-pixel G3 ranges from 1:4 to 1:2, and a ratio of the light-emitting area of the third light-emitting device EM3 of the third blue sub-pixel B3 to the light-emitting area of the first light-emitting device EM1 of the first blue sub-pixel B1 ranges from 1:4 to 1:2.

In addition, in the embodiments of the present disclosure, the comparison of the areas of the material of the gray planarization layer GO filled in the first light exit opening BM1, the second light exit opening BM2 and the first sensor opening BM0 is also for sub-pixels of the same color.

For example, for the first sub-pixel and the second sub-pixel of the same color, the light-emitting area of the first light-emitting device EM1 is substantially the same as the light-emitting area of the second light-emitting device EM2.

For example, in some embodiments, in the main display region AA, the area occupied by one first repeating unit on the display substrate is taken as a unit area, for each of the first sub-pixels, the area of the material of the gray planarization layer GO filled in the first light exit opening BM1 accounts for about 30%-50% of the unit area. For example, the area of the material of the gray planarization layer GO filled in the first light exit opening BM1 of the first blue sub-pixel B1 is greater than the area of the material of the gray planarization layer GO filled in the first light exit opening BM1 of the first red sub-pixel R1, and the area of the material of the gray planarization layer GO filled in the first light exit opening BM1 of the first red sub-pixel R1 is larger than the area of the material of the gray planarization layer GO filled in the first light exit opening BM1 of the first green sub-pixel G1.

For example, in the sensor region SS, the area occupied by a second repeating unit on the display substrate is taken as a unit area, for each of the second sub-pixels, the area of the material of the gray planarization layer GO filled in the second light exit opening BM2 accounts for about 30%-50% of the unit area. The area of the material of the gray planarization layer GO filled in the second light exit opening BM2 of the second blue sub-pixel B2 is greater than the area of the material of the gray planarization layer GO filled in the second light exit opening BM2 of the second red sub-pixel R2, and the area of the material of the gray planarization layer GO filled in the second light exit opening BM2 of the second red sub-pixel R2 is greater than the area of the material of the gray planarization layer GO filled in the second light exit opening BM2 of the second green sub-pixel G2. For example, the area of the material of the gray planarization layer GO filled in the first sensor opening BM0 accounts for about 1.8%-6.0% of the unit area.

For example, in the light-transmitting display region AA, the area occupied by a third repeating unit on the display substrate is taken as a unit area, for each of the third sub-pixels, the area of the annular light-shielding portion BM3 accounts for about 20%-28% of the unit area. The area of the material of the gray planarization layer GO filled in the annular light-shielding portion BM3 of the third blue sub-pixel B3 is larger than the area of the material of the gray planarization layer GO filled in the annular light-shielding portion BM3 of the third red sub-pixel R3, and the area of the material of the gray planarization layer GO filled in the annular light-shielding portion BM3 of the third red sub-pixel R3 is larger than the area of the material of the gray planarization layer GO filled in the annular light-shielding portion BM3 of the third green sub-pixel G3.

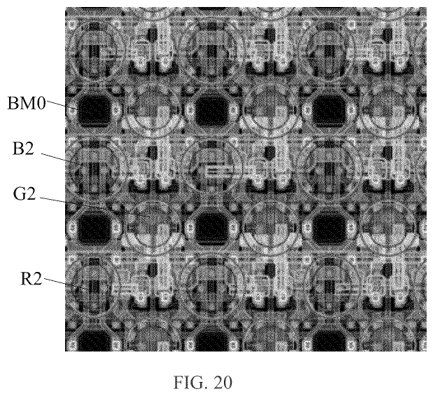

For example, FIG. 19 and FIG. 20 respectively show partial planar schematic diagrams of a main display region AA and a sensor region SS in a display panel provided by at least one embodiment of the present disclosure. As shown in FIG. 20, each of the second repeating units is provided with a first sensor opening BM0, and the first sensor opening BM0 is surrounded by one second red sub-pixel R2, two second green sub-pixels G2 and one second blue sub-pixel B2. As shown in FIG. 19, the sub-pixel arrangement of the main display region AA is the same as the sub-pixel arrangement of the sensor region SS, and the difference is that the black matrix layer BM located in the main display region AA does not have the first sensor opening BM0.

For example, in some embodiments, as shown in FIG. 2, in the main display region AA, the first light-emitting device EM1 includes a first anode pattern 11, a first light-emitting pattern 12 and a first cathode layer 13 that are arranged in a stack, for example, the first anode pattern 11, the first light-emitting pattern 12 and the first cathode layer 13 are stacked in sequence in a direction away from the base substrate 101, the first cathode layers 13 of the first light-emitting devices EM1 of the plurality of first sub-pixels are continuously arranged in the main display region AA, that is, the first cathode layer 13 is formed integrally in the main display region AA.

For example, in the sensor region SS, the second light-emitting device EM2 includes a second anode pattern 21, a second light-emitting pattern 22, and a second cathode layer 23 that are arranged in a stack, for example, the second anode pattern 21, the second light-emitting pattern 22 and the second cathode layer 23 are stacked in sequence in a direction away from the base substrate 101, the second cathode layers 23 of the second light-emitting devices EM2 of the plurality of second sub-pixels are continuously arranged in the sensor region SS, that is, the second cathode layer 23 is formed integrally in the sensor region SS.

For example, in some examples, in the sensor region SS, the second cathode layers 23 may also be arranged at intervals, for example, the pixel definition layer PDL includes a plurality of second sensor openings PDL0 in the sensor region SS (details will be described later), in a direction perpendicular to the base substrate 101, the plurality of second sensor openings PDL0 are not overlapped with the second cathode layers 23, that is, there is no material of the second cathode layer 23 at the positions corresponding to the plurality of second sensor openings PDL0.

For example, in the light-transmitting display region FDC, the third light-emitting device EM3 includes a third anode pattern 31, a third light-emitting pattern 32, and a third cathode pattern 33 that are arranged in a stack, the third anode pattern 31, the third light-emitting pattern 32 and the third cathode pattern 33 are stacked in sequence in a direction away from the base substrate 101, the third cathode patterns 22 of the third light-emitting devices EM3 of the plurality of third sub-pixels are arranged at intervals in the light-transmitting display region FDC, that is, in the light-transmitting display region FDC, except for the regions where the third light-emitting devices EM3 are arranged, there is no cathode material in other regions.

For example, in some examples, in the sensor region SS, the second cathode layers 23 are spaced apart, the pixel definition layer PDL includes a plurality of second sensor openings PDL0, in the direction perpendicular to the base substrate 101, the plurality of second sensor openings PDL0 are not overlapped with the second cathode layers 23, that is, at the positions corresponding to the plurality of second sensor openings PDL0, there is no material of the second cathode layer 23; in this case, in the light-transmitting display region FDC, the third cathode patterns 22 are arranged at intervals in the light-transmitting display region FDC, furthermore, a distance between adjacent third cathode patterns 22 in the light-transmitting display region FDC is greater than a distance between adjacent second cathode layers 23 in the sensor region SS.

For example, in the embodiments of the present disclosure, a light-emitting area of one light-emitting device is equal to an opening area of the sub-pixel opening PDL1 in the corresponding pixel definition layer PDL (details will be introduced later), is also equal to an area of the light-emitting pattern formed in the sub-pixel opening PDL1.

For example, as shown in FIG. 2, the first cathode layer 13, the second cathode layer 23 and the third cathode pattern 33 are arranged in the same layer, and therefore in the manufacture process, the third cathode patterns 33 may be formed by removing the cathode material between adjacent third light-emitting devices, not arranging the cathode material between adjacent third light-emitting devices can improve the light transmittance of the light-transmitting display region FDC.

It should be noted that, in the embodiments of the present disclosure, “arranged in a/the same layer” means that two (or more) functional layers or structural layers are formed in the same layer and with the same material in a hierarchical structure of the display substrate, that is, in the manufacture process, the two (or more) functional layers or structural layers can be formed from the same material layer, and the required patterns and structures can be formed through the same patterning process.

For example, as shown in FIG. 2, the light-emitting device layer EM further includes a pixel definition layer PDL for defining different sub-pixels, the pixel definition layer PDL includes a plurality of sub-pixel openings PDL1 in the main display region AA, the sensor region SS and the light-transmitting display region FDC, the sub-pixel openings PDL1 are used to form light-emitting patterns. In the sensor region SS, the pixel definition layer PDL includes a second sensor opening PDL0 at least partially overlapping with the first sensor opening BM0 in the direction perpendicular to the base substrate 101. In the light-transmitting display region FDC, the pixel definition layer PDL includes a plurality of sub-pixel walls PDL2 for defining a plurality of third sub-pixel openings, and the plurality of sub-pixel walls PDL2 are arranged at intervals, that is, in the light-transmitting display region FDC, except for the plurality of sub-pixel walls PDL2 used to define different sub-pixels, there is no material of the pixel definition layer PDL in other regions, in this way, the light transmittance of the light-transmitting display region FDC can be improved.

For example, in some embodiments, the pixel definition layer PDL may be a black pixel definition layer, thus the second sensor opening PDL0 is provided in the pixel definition layer PDL to transmit light for the sensor S, the pixel definition layer PDL forms the plurality of sub-pixel walls PDL2 at intervals in the light-transmitting display region FDC, which can improve the light transmittance of the light-transmitting display region FDC. For example, the pixel definition layer PDL in the main display region AA, the sensor region SS, and the light-transmitting display region FDC are arranged in the same layer, in the manufacture process, the plurality of sub-pixel walls PDL2 in the light-transmitting display region FDC may be formed by removing the material of the pixel definition layer PDL between adjacent third light-emitting devices.

For example, in other embodiments, the pixel definition layer PDL may be a light-transmitting pixel definition layer, the light-transmitting pixel definition layer has high light transmittance, in this case, the light-transmitting pixel definition layer may be provided with the above second sensor opening PDL0, or may not be provided with the second sensor opening PDL0, in the light-transmitting display region FDC, the light-transmitting pixel definition layer may be arranged at intervals or continuously.

For example, in other embodiments, the plurality of third sub-pixels in the light-transmitting display region FDC may also have different arrangements. For example, FIG. 4 shows a partial cross-sectional schematic diagram of another display panel provided by at least one embodiment of the present disclosure.

For example, as shown in FIG. 4, the light-transmitting display region FDC may include a sub-pixel setting region FDC1 and a sub-pixel removal region FDC2, the sub-pixel setting region FDC1 includes a plurality of third sub-pixels, the sub-pixel removal region FDC2 does not include a sub-pixel, for example, also does not include various structures and materials used to form the sub-pixel, such as the pixel definition layer, the anode, the light-emitting layer and the cathode of the light-emitting device, etc., the sub-pixel removal region FDC2 is only used for light transmission. For example, a ratio of the area of the sub-pixel setting region FDC1 to the area of the sub-pixel removal region FDC2 ranges from 1:3 to 1:1, such as 1:1, 1:2 or 1:3.

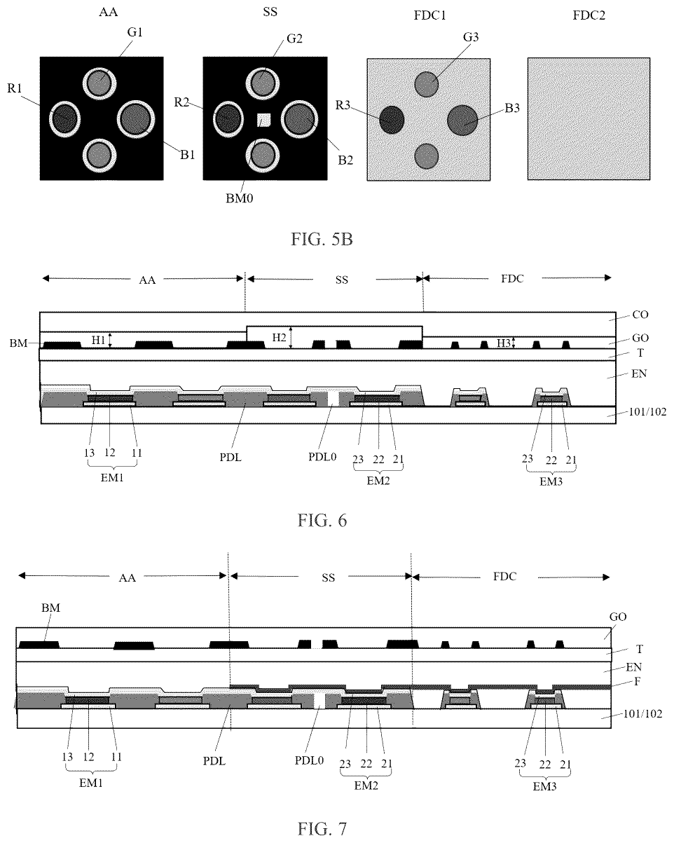

For example, FIG. 5A shows a partial planar schematic diagram of the main display region AA, the sensor region SS, and the light-transmitting display region FDC in the above embodiments. As shown in FIG. 5A, an arrangement density of the first light-emitting devices EM1 in the main display region AA is equal to an arrangement density of the third light-emitting devices EM3 in the sub-pixel setting region FDC1, and is also equal to an arrangement density of the second light-emitting devices EM2 in the sensor area SS. The light-emitting area of the third light-emitting device EM3 is equal to the light-emitting area of the first light-emitting device EM1, that is, in the third light-emitting device EM3 and the first light-emitting device EM1 that emit light of the same color, the light-emitting area of the third light-emitting device EM3 is equal to the light-emitting area of the first light-emitting device EM1; for example, in the second light-emitting device EM2 and the first light-emitting device EM1 that emit light of the same color, the light-emitting area of the second light-emitting device EM2 is also equal to the light-emitting area of the first light-emitting device EM1.

For example, in some embodiments, as shown in FIG. 5A, the sub-pixel setting region FDC1 may further include a plurality of first wiring lines L1 arranged at edges of the plurality of third sub-pixels, as shown in FIG. 4 and FIG. 5A, in the sub-pixel setting region FDC1, the black matrix layer BM includes a plurality of first shielding lines BM4 at least partially overlapping with the plurality of first wiring lines L1 in the direction perpendicular to the base substrate 101, the black matrix layer BM is hollowed out in the sub-pixel removal region FDC2, thereby improving the light transmittance of the light-transmitting display region FDC.

For example, in some embodiments, the plurality of first wiring lines L1 may be the plurality of touch wiring lines in the touch layer T.

For example, in the embodiment of FIG. 4 and FIG. 5A, the pixel definition layer PDL is also hollowed out in the sub-pixel removal region FDC2 to increase the light transmittance of the light-transmitting display region FDC. For example, the arrangement method of the pixel definition layer PDL in the sub-pixel setting region FDC1 in basically the same as the arrangement method of the pixel definition layer PDL in the main display region AA and the sensor region SS.

For example, FIG. SB shows a partial planar schematic diagram of the black matrix around the sub-pixels in the embodiment of FIG. 4 and FIG. 5A. As shown in FIG. 4 and FIG. 5A, in the main display region AA, the black matrix layer BM includes a plurality of first light exit openings BM1 exposing the first light-emitting devices EM1 of the plurality of first sub-pixels. In the sensor region SS, the black matrix layer BM includes a plurality of second light exit openings BM2 exposing the second light-emitting devices EM2 of the plurality of second sub-pixels, and the black matrix layer BM is hollowed out in most regions of the light-transmitting display region FDC.

For example, as shown in FIG. 5B, in this embodiment, a material of the gray planarization layer GO is filled in the plurality of first light exit openings BM1, the plurality of second light exit openings BM2 and the first sensor opening BM0, an area of the material of the gray planarization layer GO filled in the plurality of first light exit openings BM1 is greater than an area of the material of the gray planarization layer GO filled in the first sensor opening BM0, and an area of the material of the gray planarization layer GO filled in the plurality of second light exit openings BM2 is larger than the area of the material of the gray planarization layer GO filled in the first sensor opening BM0. For example, the area of the material of the gray planarization layer GO filled in the plurality of first light exit openings BM1 is substantially equal to the area of the material of the gray planarization layer GO filled in the plurality of second light exit openings BM2.

For example, in other embodiments, thicknesses of the gray planarization layer GO in different regions may be different, to reduce reflectivity difference in the light-transmitting display region FDC, the sensor region SS and the main display region AA, so that visual display effects of the light-transmitting display region FDC, the sensor region SS and the main display region AA are basically the same.

For example, in some embodiments, as shown in FIG. 6, in the direction perpendicular to the base substrate 101, a first thickness H1 of the gray planarization layer GO in the main display region AA (for example, a maximum thickness in the main display region AA, and also a thickness at the position where there is no material of the black matrix layer BM) may range from 2 μm to 3 μm, such as 2.2 μm, 2.5 μm, or 2.8 μm, etc., a second thickness H2 of the gray planarization layer GO in the sensor region SS (for example, a maximum thickness in the sensor region SS, and also a thickness at the position where there is no material of the black matrix layer BM) is higher than the first thickness H1 by 0.2 μm to 0.5 μm, for example, the second thickness H2 may range from 2.2 μm to 3.5 μm, such as 2.5 μm, 2.8 μm, 3.0 μm or 3.2 μm, etc.; and a third thickness H3 of the gray planarization layer GO in the light-transmitting display region FDC (for example, a maximum thickness in the light-transmitting display region FDC, also a thickness at the position where there is no material of the black matrix layer BM) is lower than the first thickness H1 by 0.4 μm to 0.6 μm, for example, 0.5 μm, for example, the third thickness H3 may range from 1.5 μm to 2.5 μm, such as 1.8 μm, 2.0 μm or 2.2 μm, etc.

Through experimental verification, taking light with a wavelength of 530 nm as an example, in a case that the thickness of the gray planarization layer GO is 1.5 μm, the light transmittance of the gray planarization layer GO is 72%; in a case that the thickness of the gray planarization layer GO is 2 μm, the light transmittance of the gray planarization layer GO is 64%; in a case that the thickness of the gray planarization layer GO is 2.5 μm, the light transmittance of the gray planarization layer GO is 58%; in a case that the thickness of the gray planarization layer GO is 3 μm, the light transmittance of the gray planarization layer GO is 51%; in a case that the thickness of the gray planarization layer GO is 3.5 μm, the light transmittance of the gray planarization layer GO is 46%. In addition, in a case that the second thickness H2 of the gray planarization layer GO in the sensor region SS is higher than the first thickness H1 of the gray planarization layer GO in the main display region AA by 0.2 μm, the reflectivity difference between the sensor region SS and the main display region AA is 0.29%, in a case that the second thickness H2 is higher than the first thickness H1 by 0.3 μm, the reflectivity difference between the sensor region SS and the main display region AA is 0.44%; in a case that the second thickness H2 is higher than the first thickness H1 by 0.5 μm, the reflectivity difference between the sensor region SS and the main display region AA is 0.70%; in a case that the second thickness H2 is higher than the first thickness H1 by 0.8 μm, the reflectivity difference between the sensor region SS and the main display region AA is 1.20%.

In this way, in a case that the second thickness H2 is higher than the first thickness H1 by 0.2 μm to 0.5 μm, the reflectivity difference between the sensor region SS and the main display region AA can be reduced by about 0.29% to 0.7%, and the difference in visual display effects between the sensor region SS and the main display region AA is significantly reduced.

In this way, in a case that the thickness of the gray planarization layer GO is different, its light transmittance is different, by adjusting the thicknesses of the gray planarization layer GO in different regions, the light transmittance of the gray planarization layer GO can be different in different regions, so that the reflectivity difference in different regions of the display panel is reduced, and the uniformity of the overall visual display effect of the display panel is improved.

For example, as shown in FIG. 6, in this embodiment, the display panel may further include a covering layer CO, the covering layer CO is arranged on a side of the gray planarization layer GO away from the base substrate 101, to planarize the gray planarization layer GO. For example, a material of the covering layer CO may be an organic insulating material such as polyimide and resin, or an inorganic insulating material such as silicon oxide, silicon nitride, and silicon oxynitride.

It should be noted that, in FIG. 6 and the following figures, the base substrate 101 and the driving circuit layer 102 are not shown separately for simplicity of illustration, their position relationship can be seen in FIG. 2 and FIG. 4.

For example, in other embodiments, the reflectivity difference between the light-transmitting display region FDC, the sensor region SS and the main display region AA can also be reduced in other ways, so that the overall visual display effects of the light-transmitting display region FDC, the sensor region SS and the main display region AA are basically the same.

For example, in some embodiments, as shown in FIG. 7, the display panel may further include an anti-reflection layer F, the anti-reflection layer F is located in the sensor region SS and the light-transmitting display region FDC, and is located on a side of the second light-emitting device EM2 or the third light-emitting device EM3 away from the base substrate 101, that is, located on a side of the second cathode layer 23 or the third cathode pattern 33 away from the base substrate 101, in this case, the encapsulation layer EN is located on a side of the anti-reflection layer F away from the base substrate 101.

For example, in some embodiments, a material of the anti-reflection layer F may include at least one of ytterbium, bismuth, calcium fluoride, magnesium fluoride and other materials, in the direction perpendicular to the base substrate 101, a thickness of the anti-reflection layer F ranges from 8 nm to 10 nm, such as 8.5 nm, 9.0 nm or 9.5 nm.

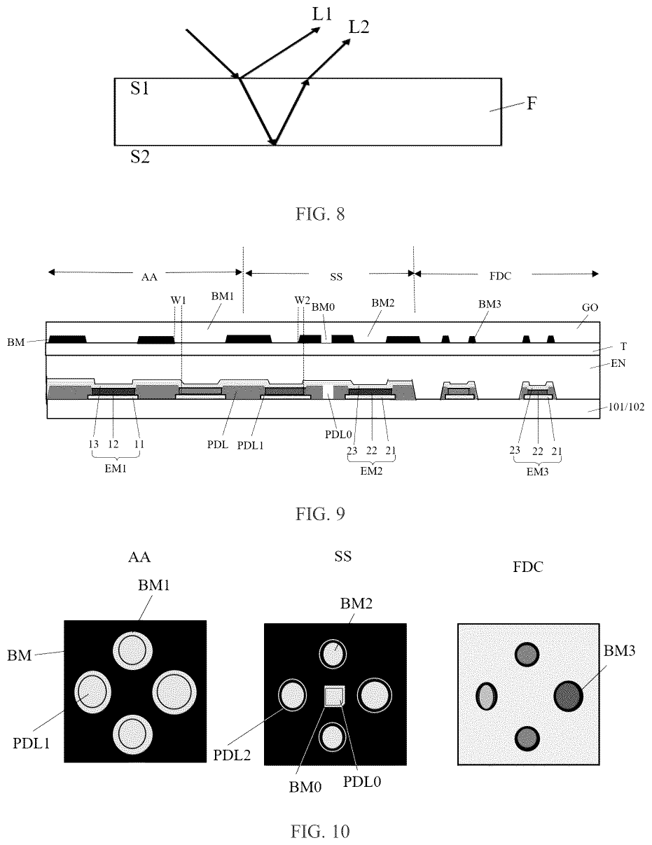

For example, FIG. 8 shows a principle diagram of the anti-reflection layer F to reduce reflectivity, as shown in FIG. 8, the anti-reflection layer F has an upper surface S1 and a lower surface S2, external light incident on the anti-reflective layer F can be reflected by the upper surface S1 as light L1, the external light incident on the anti-reflection layer F can be reflected by the lower surface S2 as light L2, phases of light L1 and light L2 can be opposite to each other, so the interference cancellation occurs, thus the reflectivity of the region where the anti-reflection layer F is provided is greatly reduced, that is, the reflectivity of the sensor region SS and the reflectivity of the light-transmitting display region FDC are greatly reduced, so that the overall visual display effects of the light-transmitting display region FDC, the sensor region SS and the main display region AA are basically the same.

For example, in other embodiments, the black matrix layer can also be designed differently in different regions, to reduce the reflectivity difference between the light-transmitting display region FDC, the sensor region SS and the main display region AA, so that the visual display effects of the light-transmitting display region FDC, the sensor region SS and the main display region AA are basically the same.

For example, in some embodiments, as shown in FIG. 9, the pixel definition layer PDL includes a plurality of sub-pixel openings PDL1 in the main display region AA, the sensor region SS, and the light-transmitting display region. In the main display region AA, a first orthographic projection of the sub-pixel opening PDL1 on the base substrate 101 is located within a second orthographic projection of the first light exit opening BM1 on the base substrate 101, that is, in the main display region AA, the sub-pixel opening PDL1 is contracted inwardly relative to the first light exit opening BM1, for example, a contracted distance W1 ranges from 3 μm to 6 μm, such as 4 μm, 5 μm or 6 μm, etc. In the sensor region SS, a third orthographic projection of the second light exit opening BM2 on the base substrate 101 is located within a fourth orthographic projection of the sub-pixel opening PDL1 on the base substrate 101, that is, in the sensor region SS, the second light exit opening BM2 is contracted inwardly relative to the sub-pixel opening PDL1. For example, a contracted distance W2 of the second light exit opening BM2 relative to the sub-pixel opening PDL1 ranges from 1 μm to 4 μm, such as 2 μm, 3 μm or 4 μm, etc., that is, the third orthographic projection is contracted inwardly by 1 μm to 4 μm relative to the fourth orthographic projection, such as 2 μm, 3 μm, or 4 μm.

For example, FIG. 10 shows a partial planar schematic diagram of the light-transmitting display region FDC, the sensor region SS, and the main display region AA in the embodiment of FIG. 9. As shown in FIG. 9 and FIG. 10, in this embodiment, the black matrix layer BM includes a plurality of annular light-shielding portions BM3 in the light-transmitting display region FDC, the plurality of annular light-shielding portions BM3 are arranged at intervals. Therefore, the arrangement area of the black matrix layer BM in the light-transmitting display region FDC is much smaller than the arrangement area of the black matrix layer BM in the main display region AA.

For example, as shown in FIG. 10, in the sensor region SS, the pixel definition layer PDL includes a second sensor opening PDL0 at least partially overlapping with the first sensor opening BM0 in the direction perpendicular to the base substrate 101, and the second sensor opening PDL0 is contracted inwardly relative to the first sensor opening BM0 in the black matrix layer BM.

Through testing, in the above embodiment, the light reflectivity of the sensor region SS can be reduced by about 0.2% to 0.6%, thus the difference in light reflectivity between the sensor region SS and the main display region AA can be reduced by about 0.2% to 0.6%.

For example, in the embodiment of FIG. 10, the black matrix layer BM includes a plurality of annular light-shielding portions BM3 in the light-transmitting display region FDC, which is basically the same as the implementation of the embodiment of FIG. 2, for details, please refer to the above-mentioned embodiments.

For example, in other embodiments, as shown in FIG. 11, in the sensor region SS, the pixel definition layer PDL includes a second sensor opening PDL0 at least partially overlapping with the first sensor opening BM0 in the direction perpendicular to the base substrate 101, the second cathode layers 23 of the second light-emitting devices EM2 are continuously arranged in the sensor region SS, and the second cathode layers 23 include a third sensor opening 230 at least partially overlapping with the first sensor opening BM0 in the direction perpendicular to the base substrate 101, at the same time, the third sensor opening 230 also at least partially overlaps with the second sensor opening PDL0.

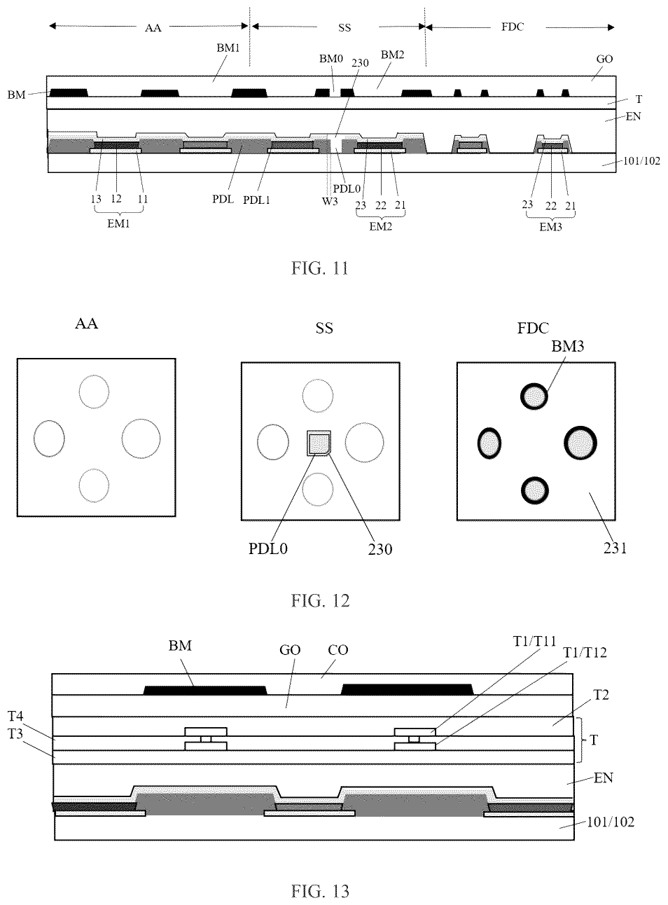

For example, FIG. 12 shows a partial planar schematic diagram of the light-transmitting display region FDC, the sensor region SS, and the main display region AA in the embodiment of FIG. 11. As shown in FIG. 11 and FIG. 12, a fifth orthographic projection of the second sensor opening PDL0 on the base substrate 101 is located within a sixth orthographic projection of the third sensor opening 230 on the base substrate 101, that is, the second sensor opening PDL0 is contracted inwardly relative to the third sensor opening 230, that is, the fifth orthographic projection shrinks inwardly relative to the sixth orthographic projection, for example, the shrinkage distance W3 ranges from 1.0 μm to 2.0 μm, such as 1.2 μm, 1.5 μm, or 1.8 μm.

For example, as shown in FIG. 11 and FIG. 12, in this embodiment, in the light-transmitting display region FDC, the third cathode patterns 23 of the third light-emitting devices EM3 of the third sub-pixels are arranged at intervals, that is, in FIG. 12, there is no cathode material at the position, labeled 231, where there is no light-emitting device. In this way, the light transmittance of the light-transmitting display region FDC can be improved.

For example, in some embodiments, the first light-emitting patterns 12 located in the main display region AA are continuously arranged, the second light-emitting patterns 22 located in the sensor region SS are continuously arranged, the third light-emitting patterns 32 located in the light-transmitting display region FDC are arranged at intervals. For example, in some examples, the first light-emitting patterns 12 and the second light-emitting patterns 22 may also be continuously arranged.

For example, in other embodiments, the black matrix layer BM and the gray planarization layer GO may also have different arrangements.

For example, as shown in FIG. 13, the display panel further includes a touch layer T, which is arranged on a side of the encapsulation layer EN away from the base substrate 101, the touch layer T includes a touch wiring layer T1 and a touch insulation layer T2 located on a side of the touch wiring layer T1 away from the base substrate 101. For example, the touch insulating layer T2 may be made of an organic insulating material such as polyimide and resin.

For example, the gray planarization layer GO is arranged on a side of the touch insulating layer T2 away from the base substrate 101, and the black matrix layer BM is arranged on a side of the gray planarization layer GO away from the base substrate 101

For example, as shown in FIG. 13, the display panel may further include a covering layer CO, the covering layer CO is arranged on a side of the black matrix layer BM away from the base substrate 101, to planarize the black matrix layer BM. For example, the covering layer CO may be an organic covering layer or an inorganic covering layer, the organic covering layer may include an organic insulating material such as polyimide and resin, and the inorganic covering layer may include an inorganic insulating material such as silicon oxide, silicon nitride, and silicon oxynitride.

For example, as shown in FIG. 13, the touch wiring layer T1 may include a first touch wiring layer T11 and a second touch wiring layer T12, the first touch wiring layer T11 is arranged on a side of the second touch wiring layer T12 away from the base substrate 101, the first touch wiring layer T11 and the second touch wiring layer T12 are separated by an insulating layer T4. For example, the first touch wiring layer T11 and the second touch wiring layer T12 respectively include a plurality of touch wiring lines, and some of the touch wiring lines in the first touch wiring layer T11 and the second touch wiring layer T12 may be electrically connected through vias in the insulating layer T4, which serve as bridge connection structures of the touch wiring layer T1.

For example, as shown in FIG. 13, the touch layer T may further include a touch buffer layer T3, the touch buffer layer T3 is arranged on a side of the encapsulation layer EN away from the base substrate 101, and the touch wiring layer T1 is arranged on a side of the touch buffer layer T3 away from the base substrate 101.

For example, in other embodiments, the touch layer T, the black matrix layer BM and the gray planarization layer GO may also have different arrangement methods.

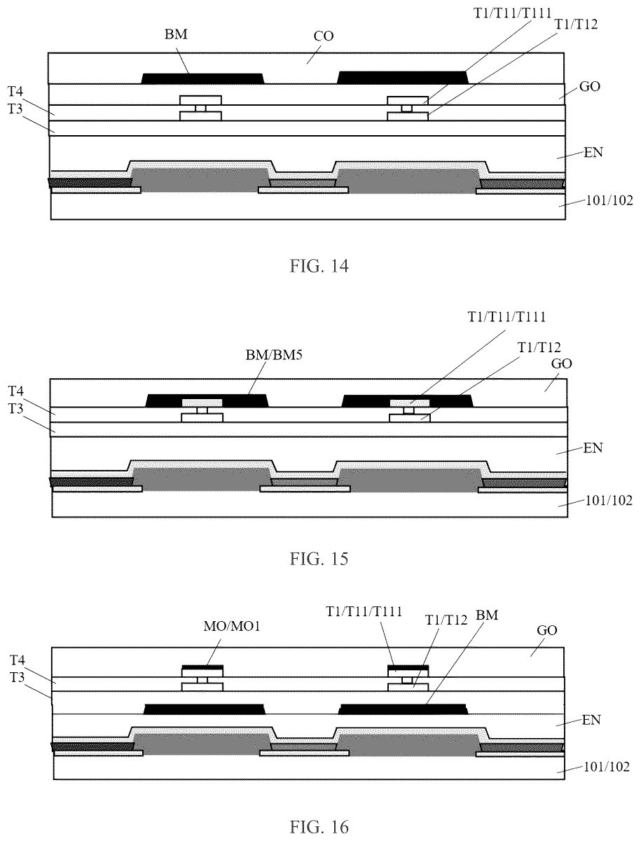

For example, as shown in FIG. 14, in some embodiments, the touch layer T is arranged on a side of the encapsulation layer EN away from the base substrate 101, the touch layer T includes a touch wiring layer T1, the touch wiring layer T1 includes a plurality of touch wiring lines T111. The gray planarization layer GO is arranged on the side of the touch wiring layer T1 away from the base substrate 101, and is in contact with the plurality of touch wiring lines T111, thereby realizing the function of insulating the plurality of touch wiring lines T111. Compared with the embodiment of FIG. 13, the touch insulation layer T2 is omitted, in the manufacture process, a mask process for manufacturing the touch insulation layer T2 is saved. In this case, as shown in FIG. 14, the black matrix layer BM is arranged on a side of the gray planarization layer GO away from the base substrate 101.

For example, as shown in FIG. 14, the touch wiring layer T1 may also include a first touch wiring layer T11 and a second touch wiring layer T12, the first touch wiring layer T11 is arranged on a side of the second touch wiring layer T12 away from the base substrate 101, the first touch wiring layer T11 and the second touch wiring layer T12 are separated by an insulating layer T4. The first touch wiring layer T11 and the second touch wiring layer T12 respectively include a plurality of touch wiring lines, in this case, the gray planarization layer GO contacts and covers the touch wiring lines T111 in the first touch wiring layer T11 that are further away from the base substrate 101.

For example, as shown in FIG. 13, the touch layer T may further include a touch buffer layer T3, the touch buffer layer T3 is arranged on a side of the encapsulation layer EN away from the base substrate 101, and the touch wiring layer T1 is arranged on a side of the touch buffer layer T3 away from the base substrate 101.

For example, in other embodiments, as shown in FIG. 15, the touch layer T is arranged on a side of the encapsulation layer EN away from the base substrate 101 and includes a touch wiring layer T1, the touch wiring layer T1 includes a plurality of touch wiring lines T111, the black matrix layer BM is arranged on a side of the touch trace layer T1 away from the base substrate 101 and includes a plurality of second shielding lines BM5 that are in contact with and cover the plurality of touch wiring lines T11, and the gray planarization layer GO is arranged on a side of the black matrix layer BM away from the base substrate 101. In this way, compared with the embodiment of FIG. 13, the touch insulation layer T2 is omitted, in the manufacture process, the mask process for manufacturing the touch insulation layer T2 is saved.

For example, as shown in FIG. 15, the touch wiring layer T1 may include a first touch wiring layer T11 and a second touch wiring layer T12, the first touch wiring layer T11 is arranged on a side of the second touch wiring layer T12 away from the base substrate 101, the first touch wiring layer T11 and the second touch wiring layer T12 are separated by the insulating layer T4. The first touch wiring layer T11 and the second touch wiring layer T12 respectively include a plurality of touch wiring lines, in this case, the plurality of second shielding lines BMS are in contact with and cover the touch wiring lines T111 in the first touch wiring layer T1l that is further away from the base substrate 101.

For example, as shown in FIG. 15, the touch layer T may further include a touch buffer layer T3, the touch buffer layer T3 is arranged on a side of the encapsulation layer EN away from the base substrate 101, and the touch wiring layer T1 is arranged on a side of the touch buffer layer T3 away from the base substrate 101.

For example, in other embodiments, as shown in FIG. 16, the black matrix layer BM is arranged on a side of the encapsulation layer EN away from the base substrate 101, the touch layer T is arranged on a side of the black matrix layer BM away from the base substrate 101, and includes the touch wiring layer T1, the touch wiring layer T1 includes a plurality of touch wiring lines T111, and the gray planarization layer GO is arranged on a side of the touch wiring layer T1 away from the base substrate 101. In this way, compared with the embodiment of FIG. 13, the touch insulation layer T2 is also omitted, and in the manufacture process, the mask process for manufacturing the touch insulation layer T2 is saved.

For example, as shown in FIG. 16, the display panel may further include a molybdenum oxide layer MO, a material of the molybdenum oxide layer MO includes molybdenum oxide (MOₓO_{y}/MoOₓ). The molybdenum oxide layer MO is located on a side of the plurality of touch wiring lines T11 away from the base substrate 101 and includes a plurality of covering lines MO1, to cover the plurality of touch wiring lines T11.

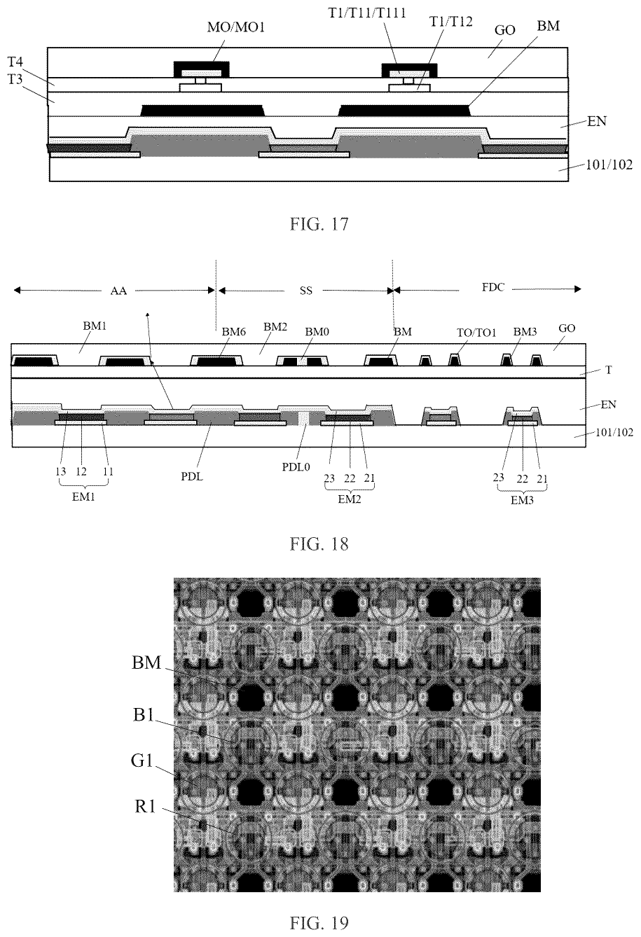

For example, as shown in FIG. 16, the plurality of covering lines MO1 can directly contact and cover the plurality of touch wiring lines T11, but does not cover sides of the plurality of touch wiring lines T11; or, in other embodiments, as shown in FIG. 17, the plurality of covering lines MO1 of the molybdenum oxide layer MO can also completely cover the plurality of touch wiring lines T11, that is, the molybdenum oxide layer MO not only covers the top of the plurality of touch wiring lines T11, but also covers the sides of the plurality of touch wiring lines T11.

In the above embodiment, the molybdenum oxide layer MO is basically black, and covers the plurality of touch wiring lines T11 to reduce the light reflectivity of the plurality of touch wiring lines T11.

For example, as shown in FIG. 16 and FIG. 17, an orthographic projection of the molybdenum oxide layer MO on the base substrate 101 is located within an orthographic projection of the black matrix layer BM on the base substrate 101, to ensure the light transmittance of the display panel.

For example, as shown in FIG. 16 and FIG. 17, in this embodiment, the touch wiring layer T1 may include a first touch wiring layer T11 and a second touch wiring layer T12, the first touch wiring layer T11 is arranged on a side of the second touch wiring layer T12 away from the base substrate 101, the first touch wiring layer T11 and the second touch wiring layer T12 are separated by an insulating layer T4. The first touch wiring layer T11 and the second touch wiring layer T12 respectively include a plurality of touch wiring lines, in this case, the plurality of covering lines MO1 contact and cover the plurality of touch wiring lines T111 in the first touch wiring layer T11 that is further away from the base substrate 101

For example, as shown in FIG. 16 and FIG. 17, the touch layer T may further include a touch buffer layer T3, the touch buffer layer T3 is arranged on a side of the black matrix layer BM away from the base substrate 101, the touch buffer layer T3 can planarize the black matrix layer BM, and the touch wiring layer T1 is arranged on a side of the touch buffer layer T3 away from the base substrate 101.

For example, in other embodiments, as shown in FIG. 18, the display panel may further include a transparent insulating layer TO. The black matrix layer BM is arranged on a side of the encapsulation layer EN away from the base substrate 101 and includes a plurality of light-shielding patterns BM6, these light-shielding patterns BM6 are used to form the above first light exit opening BM1, second light exit opening BM2, first sensor opening BM0, and annular light-shielding portion BM3, etc. For example, the transparent insulating layer TO is arranged on a side of the black matrix layer BM away from the base substrate 101 and includes a plurality of covering patterns TO1, the plurality of covering patterns TO1 respectively cover the plurality of light-shielding patterns BM6. For example, the transparent insulating layer TO is in a grid shape as a whole, and an overall pattern of the transparent insulating layer TO is basically the same as an overall pattern of the black matrix layer BM. The plurality of covering patterns TO1 cover the black matrix layer BM and are in direct contact with the black matrix layer BM. In this case, the gray planarization layer GO is located on a side of the transparent insulating layer TO away from the base substrate 101, and for example, is in direct contact with the plurality of covering patterns TO1.

For example, in the above embodiment, a refractive index of the transparent insulating layer TO is n1, and a refractive index of the gray planarization layer GO is n2, and n1<n2. In this way, the light emitted by the light-emitting device will be refracted when the light is emitted to the transparent insulating layer TO and the gray planarization layer GO, as shown by the arrow in FIG. 18, the light emitted by the light-emitting device is more inclined to emit in the direction perpendicular to the display panel, in this way, the light exit rate of the display panel can be increased, furthermore, the light exit brightness of the display panel is improved and the power consumption is reduced.

For example, in some embodiments, n2−n1≥0.05, to further improve the light exit rate of the display panel, improve the light exit brightness of the display panel and reduce the power consumption.

The embodiments of the present disclosure do not limit the material of each functional layer. For example, the base substrate 101 may be a rigid substrate such as a glass substrate or a quartz substrate or a flexible substrate made of polyimide The plurality of touch wiring lines of the touch trace layer T1 may be made of copper (Cu), aluminum (Al), titanium (Ti), molybdenum (Mo) or other metal materials or alloy materials, for example, the touch wiring lines may be formed into single-layer metal layer structures or multi-layer metal layer structures. The touch buffer layer T3 of the touch wiring layer T may be made of an inorganic insulating material such as silicon oxide, silicon nitride, or silicon oxynitride, and the insulating layer T4 may also be made of an inorganic insulating material such as silicon oxide, silicon nitride, or silicon oxynitride, or an organic insulating material such as polyimide and resin.

For example, the pixel definition layer PDL may be made of an organic insulating material such as polyimide and resin. In a case that the pixel definition layer PDL is a black pixel definition layer, the material may include an organic insulating material as a base material, such as polyimide, resin, or the like, and may further include black dyes or pigments.

For example, the anode of each of the light-emitting devices may adopt transparent metal oxides such as indium tin oxide (ITO), indium zinc oxide (IZO), and gallium zinc oxide (GZO). The material of the cathode may be lithium (Li), aluminum (Al), magnesium (Mg), silver (Ag) or other metal materials, the light-emitting pattern may include an organic light-emitting material or a quantum dot light-emitting material.

For example, the display panel may also include other structures besides the above-mentioned structures. For details, please refer to related technologies, which will not be described here.

At least one embodiment of the present disclosure provides a display device, which includes any one of the above display panels, and the display device has advantages of being thin and easy to manufacture.

For example, the display device may be a mobile phone, a tablet computer, a television, a monitor, a notebook computer, a digital photo frame, a navigator, or any other product or component with a display function.

At least one embodiment of the present disclosure further provides a manufacture method of a display panel, referring to FIG. 1 and FIG. 2, the manufacture method includes: providing a base substrate 101, forming a driving circuit layer 102 on the base substrate 101, forming a light-emitting device layer EM on a side of the driving circuit layer 102 away from the base substrate 101, forming an encapsulation layer EN on a side of the light-emitting device layer EM away from the base substrate 101, and forming a gray planarization layer GO on a side of the encapsulation layer EN away from the base substrate 101; in which the display panel has a main display region AA, a sensor region SS and a light-transmitting display region FDC. The main display region AA at least partially surrounds the sensor region SS and the light-transmitting display region FDC, the gray planarization layer GO is formed in the main display region AA, the sensor region SS and the light-transmitting display region FDC.

The above manufacture method of the display panel provided by the embodiments of the present disclosure is simpler, compared with traditional COE technology, the manufacture method can save multiple masks for manufacturing color filters, for example, for a display panel with red, green, and blue sub-pixels, three masks can be saved, and at the same time, color filter raw materials are saved, costs are saved, and a thinner display panel can be obtained.

The following statements should be noted:
(1) The drawings involve only the structure(s) in connection with the embodiment(s) of the present disclosure, and other structure(s) can be referred to common design(s).
(2) For clarity, in the drawings used to describe the embodiments of the present disclosure, the thicknesses of layers or regions are enlarged or reduced, that is, the drawings are not drawn to actual scale. It can be understood that when a component such as a layer, film, region or substrate is referred to as being “on” or “under” another component, the component may be “directly” “on” or “under” another component, or one or more intermediate components may be interposed therebetween.
(3) In case of no conflict, features in one embodiment or in different embodiments can be combined to obtain new embodiments.

What have been described above are only specific implementations of the present disclosure, the protection scope of the present disclosure is not limited thereto, and the protection scope of the present disclosure should be based on the protection scope of the claims.

1. A display panel, comprising:
a base substrate,
a driving circuit layer on the base substrate,
a light-emitting device layer on a side of the driving circuit layer away from the base substrate,
an encapsulation layer on a side of the light-emitting device layer away from the base substrate, and
a gray planarization layer on a side of the encapsulation layer away from the base substrate;
wherein the display panel is provided with a main display region, a sensor region and a light-transmitting display region, the main display region at least partially surrounds the sensor region and the light-transmitting display region, and the gray planarization layer is in the main display region, the sensor region and the light-transmitting display region.

2. The display panel according to claim 1, further comprising:
a black matrix layer on a side of the encapsulation layer away from the base substrate,
wherein the gray planarization layer is on a side of the black matrix layer away from the base substrate.

3. The display panel according to claim 2, wherein the main display region comprises a plurality of first sub-pixels, each of the plurality of first sub-pixels comprises a first light-emitting device in the light-emitting device layer,
the sensor region comprises a plurality of second sub-pixels, each of the plurality of second sub-pixels comprises a second light-emitting device in the light-emitting device layer,
the black matrix layer comprises a plurality of first light exit openings exposing first light-emitting devices in the main display region, a plurality of second light exit openings exposing second light-emitting devices in the sensor region, and a first sensor opening between the plurality of second light exit openings.

4. The display panel according to claim 3, wherein a material of the gray planarization layer is filled in the plurality of first light exit openings, the plurality of second light exit openings and the first sensor opening,
an area of the material of the gray planarization layer filled in the plurality of first light exit openings is greater than an area of the material of the gray planarization layer filled in the first sensor opening, and an area of the material of the gray planarization layer filled in the plurality of second light exit openings is larger than the area of the material of the gray planarization layer filled in the first sensor opening.

5. The display panel according to claim 3, wherein the light-transmitting display region comprises a plurality of third sub-pixels, each of the plurality of third sub-pixels comprises a third light-emitting device in the light-emitting device layer,
an arrangement density of first light-emitting devices in the main display region is equal to an arrangement density of third light-emitting devices in the light-transmitting display region, a ratio of a light-emitting area of the third light-emitting device to a light-emitting area of the first light-emitting device ranges from 1:4 to 1:2,
in the light-transmitting display region, the black matrix layer comprises a plurality of annular light-shielding portions respectively exposing the third light-emitting devices of the plurality of third sub-pixels, and the plurality of the annular light-shielding portions are arranged at intervals.

6. The display panel according to claim 5, wherein an area of a material of the gray planarization layer filled in the plurality of the annular light-shielding portions is larger than an area of a material of the gray planarization layer filled in the first sensor opening.

7. The display panel according to claim 5, wherein the first light-emitting device comprises a first anode pattern, a first light-emitting pattern and a first cathode layer that are arranged in a stack,
first cathode layers of first light-emitting devices of the plurality of first sub-pixels are continuously arranged in the main display region,
the third light-emitting device of the plurality of third sub-pixels comprises a third anode pattern, a third light-emitting pattern and a third cathode pattern that are arranged in a stack, and
third cathode patterns of third light-emitting devices of the plurality of third sub-pixels are arranged at intervals in the light-transmitting display region.

8. The display panel according to claim 5, wherein the light-emitting device layer further comprises a pixel definition layer for defining sub-pixels,
the pixel definition layer comprises a plurality of sub-pixel openings in the main display region, the sensor region and the light-transmitting display region,
in the sensor region, the pixel definition layer comprises a second sensor opening at least partially overlapping with the first sensor opening in a direction perpendicular to the base substrate, and
in the light-transmitting display region, the pixel definition layer comprises a plurality of sub-pixel walls for defining the plurality of third sub-pixel openings, and the plurality of sub-pixel walls are arranged at intervals.

9. The display panel according to claim 5, wherein the light-transmitting display region comprises a sub-pixel setting region and a sub-pixel removal region, the sub-pixel setting region comprises a plurality of third sub-pixels, the sub-pixel removal region does not comprise a sub-pixel,
a ratio of an area of the sub-pixel setting region to an area of the sub-pixel removal region ranges from 1:3 to 1:1,
each of the plurality of third sub-pixels comprises a third light-emitting device in the light-emitting device layer,
an arrangement density of first light-emitting devices in the main display region is equal to an arrangement density of third light-emitting devices in the sub-pixel setting region, a light-emitting area of the third light-emitting device is equal to a light-emitting area of the first light-emitting device,
the sub-pixel setting region further comprises a plurality of first wiring lines at edges of the plurality of third sub-pixels,
in the sub-pixel setting region, the black matrix layer comprises a plurality of first shielding lines at least partially overlapping with the plurality of first wiring lines in a direction perpendicular to the base substrate, and
the black matrix layer is hollowed out in the sub-pixel removal region.

10. The display panel according to claim 9, wherein the light-emitting device layer further comprises a pixel definition layer for defining sub-pixels, and the pixel definition layer is hollowed out in the sub-pixel removal region.

11. The display panel according to claim 1, wherein in a direction perpendicular to the base substrate,
a first thickness of the gray planarization layer in the main display region ranges from 2 μm to 3 μm,
a second thickness of the gray planarization layer in the sensor region is higher than the first thickness by 0.2 μm to 0.5 μm,
a third thickness of the gray planarization layer in the light-transmitting display region is lower than the first thickness by 0.4 μm to 0.6 μm.

12. The display panel according to claim 5, further comprising:
an anti-reflection layer, in the sensor region and the light-transmitting display region, and on a side of the second light-emitting device or the third light-emitting device away from the base substrate,
wherein the encapsulation layer is on a side of the anti-reflection layer away from the base substrate.

13. (canceled)

14. The display panel according to claim 3, wherein the light-emitting device layer further comprises a pixel definition layer for defining sub-pixels,
the pixel definition layer comprises a plurality of sub-pixel openings in the main display region, the sensor region and the light-transmitting display region,
in the main display region, a first orthographic projection of the sub-pixel opening on the base substrate is within a second orthographic projection of the first light exit opening on the base substrate, and
in the sensor region, a third orthographic projection of the second light exit opening on the base substrate is within a fourth orthographic projection of the sub-pixel opening on the base substrate.

15. (canceled)

16. The display panel according to claim 3, wherein the light-emitting device layer further comprises a pixel definition layer for defining sub-pixels,
the pixel definition layer comprises a plurality of sub-pixel openings in the main display region, the sensor region and the light-transmitting display region,
in the sensor region, the pixel definition layer comprises a second sensor opening overlapping with the first sensor opening in a direction perpendicular to the base substrate,
the second light-emitting device of each of the plurality of second sub-pixels comprises a second anode pattern, a second light-emitting pattern and a second cathode layer that are arranged in a stack,
the second cathode layer is continuously arranged in the sensor region, and comprises a third sensor opening overlapping with the first sensor opening in a direction perpendicular to the base substrate.

17-18. (canceled)

19. The display panel according to claim 1, further comprising:
a touch layer, on a side of the encapsulation layer away from the base substrate, and comprising a touch wiring layer and a touch insulation layer on a side of the touch wiring layer away from the base substrate, wherein the gray planarization layer is on a side of the touch insulation layer away from the base substrate, and
a black matrix layer, on a side of the gray planarization layer away from the base substrate; or
the display panel further comprising:
a touch layer, on a side of the encapsulation layer away from the base substrate, and comprising a touch wiring layer, wherein the touch wiring layer comprises a plurality of touch wiring lines, the gray planarization layer is on a side of the touch wiring layer away from the base substrate, and is in contact with the plurality of touch wiring lines, and
a black matrix layer, on a side of the gray planarization layer away from the base substrate; or
the display panel further comprising:
a touch layer, on a side of the encapsulation layer away from the base substrate, and comprising a touch wiring layer, wherein the touch wiring layer comprises a plurality of touch wiring lines, and
a black matrix layer, on a side of the touch wiring layer away from the base substrate, and comprising a plurality of second shielding lines that contact and cover the plurality of touch wiring lines,
wherein the gray planarization layer is on a side of the black matrix layer away from the base substrate;
or
the display panel further comprising:
a black matrix layer, on a side of the encapsulation layer away from the base substrate, and
a touch layer, on a side of the black matrix layer away from the base substrate, comprising a touch wiring layer, wherein the touch wiring layer comprises a plurality of touch wiring lines;
wherein the gray planarization layer is on a side of the touch wiring layer away from the base substrate.

20-23. (canceled)

24. The display panel according to claim 1, further comprising:
a black matrix layer, on a side of the encapsulation layer away from the base substrate, and comprising a plurality of light-shielding patterns, and
a transparent insulating layer, on a side of the black matrix layer away from the base substrate, and comprising a plurality of covering patterns, wherein the plurality of covering patterns respectively cover the plurality of light-shielding patterns,
wherein the gray planarization layer is on a side of the transparent insulating layer away from the base substrate.

25. The display panel according to claim 24, wherein a refractive index of the transparent insulating layer is n1, a refractive index of the gray planarization layer is n2, and n1<n2.

26. (canceled)

27. The display panel according to claim 1, wherein a light transmittance of the gray planarization layer ranges from 40% to 60%.

28-29. (canceled)

30. A display device, comprising the display panel according to claim 1.

31. A manufacture method of a display panel, comprising:
providing a base substrate,
forming a driving circuit layer on the base substrate,
forming a light-emitting device layer on a side of the driving circuit layer away from the base substrate,
forming an encapsulation layer on a side of the light-emitting device layer away from the base substrate, and
forming a gray planarization layer on a side of the encapsulation layer away from the base substrate;
wherein the display panel is provided with a main display region, a sensor region and a light-transmitting display region, the main display region at least partially surrounds the sensor region and the light-transmitting display region, and the gray planarization layer is formed in the main display region, the sensor region and the light-transmitting display region.
